(19) United States
(12) Patent Application Publication
(10) Pub. No.: US 2025/0050377 A1
(43) Pub. Date: Feb. 13, 2025

(54) HYDROPHOBIZATION TREATMENT APPARATUS, HYDROPHOBIZATION TREATMENT METHOD, AND COMPUTER STORAGE MEDIUM

(71) Applicant: Tokyo Electron Limited, Tokyo (JP)

(72) Inventor: Teruhiko KODAMA, Koshi City (JP)

(21) Appl. No.: 18/789,854

(22) Filed: Jul. 31, 2024

(30) Foreign Application Priority Data
Aug. 10, 2023 (JP) 2023-130660

(51) Int. Cl. B05D 5/08; B05C 5/02; B05C 15/00; B05D 1/00

(52) U.S. Cl. CPC B05D 5/08; B05C 5/02; B05C 15/00; B05D 1/60

(57) ABSTRACT

A hydrophobization treatment apparatus for performing a hydrophobization treatment on a substrate, includes: a treatment container configured to house the substrate and form a treatment space; a first supply port configured to supply first gas from above the substrate in the treatment container to the substrate; and a second supply port configured to supply second gas from a position facing a central region of the substrate below the substrate in the treatment container to the substrate, the hydrophobization treatment apparatus being configured to be able to supply a hydrophobizing gas as the first gas from the first supply port and the second gas from the second supply port.

### CROSS REFERENCE TO RELATED APPLICATIONS

This application is based upon and claims the benefit of priority of the prior Japanese Patent Application No. 2023-130660, filed in Japan on Aug. 10, 2023, the entire contents of which are incorporated herein by reference.

### TECHNICAL FIELD

This disclosure relates to a hydrophobization treatment apparatus, a hydrophobization treatment method, and a computer storage medium.

### BACKGROUND

International Publication Pamphlet No. WO 2022/196336 discloses a substrate processing device for forming a friction reducing film on the back surface of a substrate. The substrate processing device includes: a processing container that stores the substrate and provides a sealed processing space; a heating part for heating the back surface of the substrate in the processing container; and a supply part for supplying, toward the back surface of the substrate in the processing container, a material for forming the friction reducing film. The substrate processing device further includes: a first gas supply part that supplies an inert gas from above the substrate in the processing container to a peripheral edge portion of the substrate; a second gas supply part that supplies an inert gas from above the substrate in the processing container toward a side closer to the center of the substrate than the first gas supply part; and an exhaust part for exhausting an atmosphere of the processing space from around or below the substrate in the processing container.

### SUMMARY

An aspect of this disclosure is a hydrophobization treatment apparatus for performing a hydrophobization treatment on a substrate, including: a treatment container configured to house the substrate and form a treatment space; a first supply port configured to supply first gas from above the substrate in the treatment container to the substrate; and a second supply port configured to supply second gas from a position facing a central region of the substrate below the substrate in the treatment container to the substrate, the hydrophobization treatment apparatus being configured to be able to supply a hydrophobizing gas as the first gas from the first supply port and the second gas from the second supply port.

### BRIEF DESCRIPTION OF THE DRAWINGS

FIG. 1 is a cross-sectional view schematically illustrating the outline of a configuration of a hydrophobization treatment apparatus according to an embodiment.

FIG. 2 is a bottom view of a lid part of an upper member.

FIG. 3 is a flowchart illustrating main steps of Example 1 of a treatment sequence.

FIG. 4 is a view illustrating a state of a treatment container during execution of Example 1 of the treatment sequence.

FIG. 5 is a view illustrating the state of the treatment container during execution of Example 1 of the treatment sequence.

FIG. 6 is a view illustrating the state of the treatment container during execution of Example 1 of the treatment sequence.

FIG. 7 is a flowchart illustrating main steps of Example 2 of the treatment sequence.

FIG. 8 is a view illustrating a state of the treatment container during execution of Example 2 of the treatment sequence.

FIG. 9 is a view illustrating the state of the treatment container during execution of Example 2 of the treatment sequence.

FIG. 10 is a flowchart illustrating main steps of Example 3 of the treatment sequence.

FIG. 11 is a flowchart illustrating main steps of Example 4 of the treatment sequence.

FIG. 12 is a view for explaining Modification 1 of Example 4 of the treatment sequence.

FIG. 13 is a flowchart illustrating main steps of Example 5 of the treatment sequence.

FIG. 14 is a view for explaining Modification 2 of Example 4 of the treatment sequence.

FIG. 15 is a view for explaining a modification of Example 1 of the treatment sequence.

### DETAILED DESCRIPTION

In a photolithography in a manufacturing process of a semiconductor device or the like, a hydrophobization treatment for improving the adhesion between a substrate such as a semiconductor wafer (hereinafter, referred to as a “wafer”) and a resist solution is performed. In this hydrophobization treatment, the front surface of the substrate is hydrophobized by supplying an HMDS (Hexa Methyl Disilazane) gas to the front surface of the substrate mounted in a treatment container for a predetermined time. This can inhibit the resist film from peeling off from the front surface of the substrate at subsequent steps. In other words, the hydrophobization treatment can be called an adhesion treatment of giving adhesion of the film with respect to the surface of the substrate being a target of the treatment.

Further, a hydrophobic membrane is formed as a friction reducing film or the like by the hydrophobization treatment on the rear surface of the substrate to relieve the adsorption distortion when the substrate is chucked on a stage of an exposure apparatus so as to improve overlay in some cases. The hydrophobization treatment can be said a friction reducing treatment of bringing the surface of the substrate being a target into a friction reduced state.

It is preferable that both the hydrophobization treatment of the front surface of the substrate and the hydrophobization treatment of the rear surface can be executed.

Hence, the technique according to this disclosure makes it possible to perform a hydrophobization treatment on both a front surface and a rear surface of a substrate.

Hereinafter, a hydrophobization treatment apparatus and a hydrophobization treatment method according to embodiments will be explained with reference to the drawings. Note that, in the description and the drawings, elements having substantially the same functional configurations are denoted by the same reference signs to omit duplicate explanations.

### <Hydrophobization Treatment Apparatus>

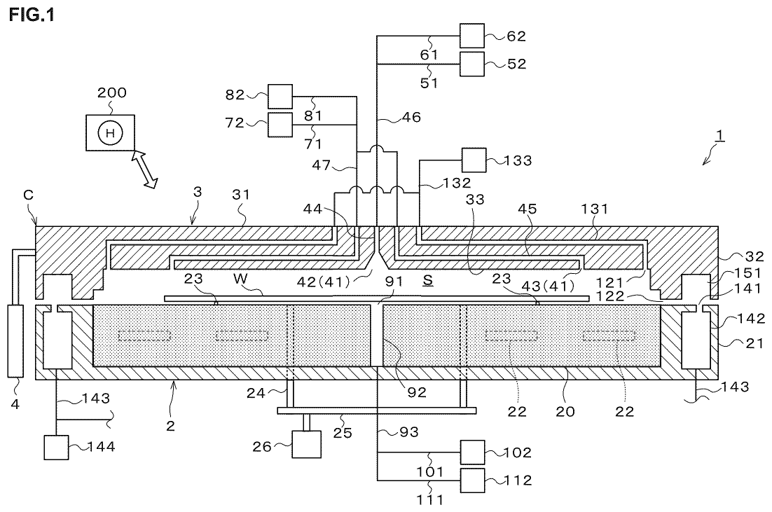

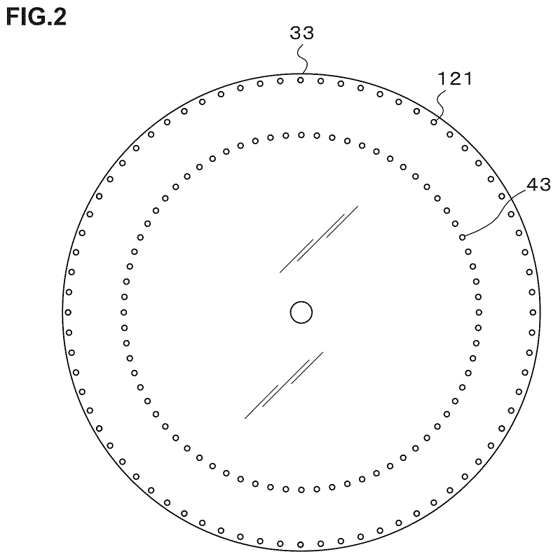

FIG. 1 is a cross-sectional view schematically illustrating the outline of a configuration of a hydrophobization treatment apparatus according to an embodiment. FIG. 2 is a bottom view of a lid part of a later-explained upper member.

A hydrophobization treatment apparatus 1 in FIG. 1 has a treatment container C which houses a wafer W as a substrate and forms a treatment space S. The treatment container C includes, for example, a lower member 2 and an upper member 3.

The lower member 2 includes a disk-shaped hot plate 20 having a radius larger than the radius of the wafer W being the substrate, and a flat cylindrical exterior part 21 surrounding other than an upper surface of the hot plate 20.

In the hot plate 20, a heater 22 is provided which is composed of a resistance heating element forming a heating part. The heater 22 is divided into, for example, a plurality of parts in a concentric circular ring about the center of the hot plate 20, and is configured to be able to heat the front surface of the hot plate 20 with high heat uniformity. Note that the heater 22 is illustrated to be divided into two parts for convenience of illustration in FIG. 1.

On the front surface of the hot plate 20, a plurality of (for example, eight) gap pins 23 are provided along a circle having a radius smaller than the radius of the wafer W around the center of the hot plate 20. The height of each gap pin 23 is set to, for example, 0.1 mm from the front surface of the hot plate 20. Only two gap pins 23 are illustrated in FIG. 1 for convenience of illustration.

Closer to the center than the gap pins 23 on the hot plate 20, three raising and lowering pins 24 are provided penetrating the hot plate 20 in a circumferential direction along the circle about the center of the hot plate 20. The three raising and lowering pins 24 are connected to a raising and lowering mechanism 26 via a raising and lowering member 25. The raising and lowering mechanism 26 has a drive source (not illustrated) such as a motor which generates driving force for raising and lowering the raising and lowering pins 24. Note that only two raising and lowering pins 24 are illustrated in FIG. 1 for convenience of illustration.

The upper member 3 has a flat cylindrical lid part 31 in a manner to cover an upper space of the lower member 2. A lower surface of a peripheral wall part 32 of the lid part 31 is formed to be able to get closer to an upper surface of an outer peripheral portion of the exterior part 21. The lid part 31 is configured to be able to rise and lower between a first position and a second position by a raising and lowering mechanism 4. The first position is a position where the lower surface of the peripheral wall part 32 of the lid part 31 and the upper surface of the outer peripheral portion of the exterior part 21 are close to each other, and the second position is a position where the wafer W is delivered between an external substrate transfer mechanism (not illustrated) and the raising and lowering pins 24. The lid part 31 lowered to the first position forms the treatment space S between itself and the lower member 2. Specifically, a ceiling part 33 of the lid part 31 lowered to the first position facing the hot plate 20 and the peripheral wall part 32 form the treatment space S between themselves and the hot plate 20.

The ceiling part 33 of the lid part 31 has a first supply port 41 for supplying first gas from above a wafer W in the treatment container C to the wafer W. The first supply port 41 is intended to selectively supply a hydrophobizing gas such as an HMDS gas or an inert gas such as a nitrogen gas as the first gas, and opens to the treatment space S.

The first supply port 41 includes, for example, a central supply port 42 and an outer peripheral supply port 43.

The central supply port 42 is formed at a position facing a later-explained second supply port 91 across the wafer W in the treatment container C. Specifically, the central supply port 42 is formed at a position of the ceiling part 33 of the lid part 31 facing the central portion of the hot plate 20.

The outer peripheral supply port 43 is formed at a position as follows. Specifically, as will be explained later, the treatment container C is configured to be exhaustable from an exhaust position outside the wafer W in the treatment container C, and the outer peripheral supply port 43 is formed between the central supply port 42 and the exhaust position on the outer side. More specifically, the outer peripheral supply port 43 is formed at a position between the central supply port 42 of the ceiling part 33 of the lid part 31 and a later-explained upper outer peripheral exhaust port 121.

The ceiling part 33 of the lid part 31 further has a central supply path 44 extending from the central supply port 42 and an outer peripheral supply path 45 extending from the outer peripheral supply port 43.

A supply pipe 46 is connected to the central supply path 44, and a supply mechanism 52 is connected to the supply pipe 46 via a branch pipe 51. The supply mechanism 52 supplies the hydrophobizing gas such as the HMDS gas to the central supply path 44 via the branch pipe 51 and the supply pipe 46. The supply mechanism 52 has, for example, a supply source, namely, a storage source (not illustrated) for the hydrophobizing gas, and a supply equipment group (not illustrated) including an opening/closing valve and a flow rate regulating valve for controlling the flow of the hydrophobizing gas. Note that the HMDS gas is, for example, a mixed gas of vapor or mist of HMDS and a carrier gas such as a nitrogen gas. The vapor or mist of HMDS is generated by vaporizing liquid of HMDS by a vaporizer or a publicly-known technique such as bubbling, and therefore its details will be omitted.

Further, a supply mechanism 62 is connected to the supply pipe 46 via a branch pipe 61. The supply mechanism 62 supplies the inert gas to the central supply path 44 via the branch pipe 61 and the supply pipe 46. The supply mechanism 62 has, for example, a supply source, namely, a storage source (not illustrated) for the inert gas, and a supply equipment group (not illustrated) including an opening/closing valve and a flow rate regulating valve for controlling the flow of the inert gas.

A supply pipe 47 is connected to the outer peripheral supply path 45, and a supply mechanism 72 is connected to the supply pipe 47 via a branch pipe 71. The supply mechanism 72 supplies the hydrophobizing gas to the outer peripheral supply path 45 via the branch pipe 71 and the supply pipe 47. The supply mechanism 72 has, for example, a supply source, namely, a storage source (not illustrated) for the hydrophobizing gas, and a supply equipment group (not illustrated) including an opening/closing valve and a flow rate regulating valve for controlling the flow of the hydrophobizing gas.

Further, a supply mechanism 82 is connected to the supply pipe 47 via a branch pipe 81. The supply mechanism 82 supplies the inert gas to the outer peripheral supply path 45 via the branch pipe 81 and the supply pipe 47. The supply mechanism 82 has, for example, a supply source, namely, a storage source (not illustrated) for the inert gas, and a supply equipment group (not illustrated) including an opening/closing valve and a flow rate regulating valve for controlling the flow of the inert gas.

As illustrated in FIG. 2, the outer peripheral supply ports 43 are provided, for example, in a circular form at a peripheral portion of the ceiling part 33. In other words, a plurality of (for example, 100 or more) outer peripheral supply ports 43 are provided, for example, along a circumferential direction of the wafer W housed in the treatment container C.

Further, as illustrated in FIG. 1, the hot plate 20 has a second supply port 91 for supplying second gas from a position facing a central region of the wafer W below the wafer W in the treatment container C to the wafer W. The second supply port 91 is intended to selectively supply a hydrophobizing gas such as an HMDS gas or an inert gas such as a nitrogen gas as the second gas, and opens to the treatment space S.

The second supply port 91 is formed at a position, of the hot plate 20, facing the central region of the wafer W in the treatment container C. Note that the “position facing the central region of the wafer W” means a position where at least a part thereof overlaps with the center of the wafer W in plan view.

The hot plate 20 further has a supply path 92 extending from the second supply port 91.

A supply pipe 93 is connected to the supply path 92, and a supply mechanism 102 is connected to the supply pipe 93 via a branch pipe 101. The supply mechanism 102 supplies the hydrophobizing gas to the supply path 92 via the branch pipe 101 and the supply pipe 93. The supply mechanism 102 has, for example, a supply source, namely, a storage source (not illustrated) for the hydrophobizing gas, and a supply equipment group (not illustrated) including an opening/closing valve and a flow rate regulating valve for controlling the flow of the hydrophobizing gas.

Further, a supply mechanism 112 is connected to the supply pipe 93 via a branch pipe 111. The supply mechanism 112 supplies the inert gas to the supply path 92 via the branch pipe 111 and the supply pipe 93. The supply mechanism 112 has, for example, a supply source, namely, a storage source (not illustrated) for the inert gas, and a supply equipment group (not illustrated) including an opening/closing valve and a flow rate regulating valve for controlling the flow of the inert gas.

Further, the treatment container C is configured to be exhaustable from the exhaust position outside the wafer W in the treatment container C. More specifically, the treatment container C has the upper outer peripheral exhaust port 121. The treatment container C may further have a lateral exhaust port 122.

The upper outer peripheral exhaust port 121 is provided above and outside the wafer W in the treatment container C, and opens to the treatment space S. The upper outer peripheral exhaust ports 121 are concretely provided, for example, in a circular form at a peripheral edge portion of the ceiling part 33. More specifically, a plurality of (for example, 100 or more) upper outer peripheral exhaust ports 121 are provided at the peripheral portion of the ceiling part 33, for example, along the circumferential direction of the wafer W housed in the treatment container C as illustrated in FIG. 2.

The ceiling part 33 of the lid part 31 has an exhaust path 131 extending from the upper outer peripheral exhaust port 121 as illustrated in FIG. 1. A exhaust mechanism 133 is connected to the exhaust path 131 via an exhaust pipe 132. The exhaust mechanism 133 has an exhauster such as a vacuum pump, and an exhaust equipment group having a vale for regulating an exhaust rate and so on.

The lateral exhaust port 122 is formed on the lateral side of the wafer W in the treatment container C and on a side lower than the upper outer peripheral exhaust port 121, in a manner to open to the treatment space S. The lateral exhaust port 122 is formed, for example, in an annular shape by a lower surface on the inside of the peripheral wall part 32 of the lid part 31 and an upper surface on the inside of the outer peripheral portion of the exterior part 21. The lateral exhaust port 122 communicates with an exhaust path 142 provided at the outer peripheral portion of the exterior part 21 via an opening 141 provided in an upper surface of the outer peripheral portion of the exterior part 21. A plurality of the openings 141 and a plurality of the exhaust paths 142 are provided, for example, along the circumferential direction of the exterior part. An exhaust mechanism 144 is connected to each exhaust path 142 via an exhaust pipe 143. The exhaust mechanism 144 has an exhauster such as a vacuum pump, and an exhaust equipment group having a vale for regulating an exhaust rate and so on.

Note that by exhausting the treatment space S via the lateral exhaust port 122 and the exhaust paths 142, an atmosphere outside the treatment container C is also sucked to the exhaust paths 142.

At a portion of the lower surface of the peripheral wall part of the lid part 31 facing the opening 141, a recess 151 recessed upward is formed. The recess 151 constitutes a buffer space for exhausting the treatment space S via the lateral exhaust port 122 uniformly in the circumferential direction.

The above hydrophobization treatment apparatus 1 is provided with a control unit 200 for controlling the hydrophobization treatment apparatus 1. The control unit 200 is composed of a computer including, for example, a processor such as a CPU, a memory, and so on, and has a program storage (not illustrated). The program storage stores a program including a command for a later-explained treatment sequence by the hydrophobization treatment apparatus 1. For example, the raising and lowering mechanisms 4, 26, the supply mechanisms 52, 62, 72, 82, 102, 112, and the exhaust mechanisms 133, 134 are controlled by the control unit 200 based on the above program. Note that the above program may be the one recorded in a computer-readable storage medium H and installed from the storage medium H into the control unit 200. The storage medium H may be a transitory one or a non-transitory one.

### Example 1 of the Treatment Sequence

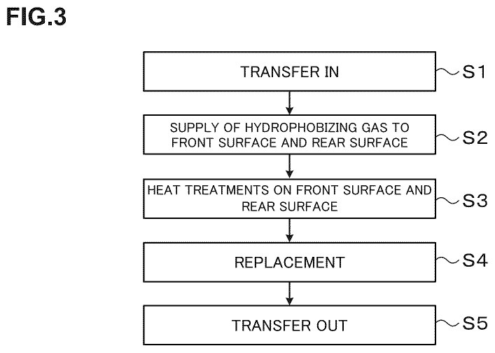

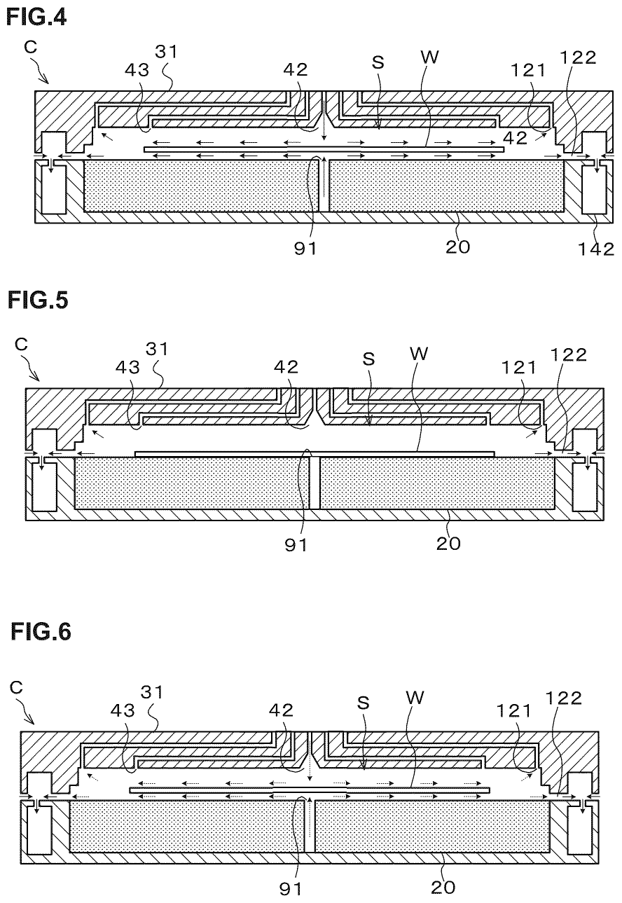

Next, an example of the treatment sequence executed by the hydrophobization treatment apparatus 1 will be explained. FIG. 3 is a flowchart illustrating main steps of Example 1 of the treatment sequence. FIG. 4 to FIG. 6 are views illustrating the states of the treatment container C during the execution of Example 1 of the treatment sequence. Note that the illustration of the raising and lowering pins 24 and the gap pins 23 is omitted in FIG. 4 to FIG. 6. Further, FIG. 4 to FIG. 6 illustrate the flow of the hydrophobizing gas in the treatment space S by solid arrows and the flow of the inert gas in the treatment space S by dotted arrows. This also applies to the following drawings.

Further, the following steps of Example 1 of the treatment sequence are executed under control of the control unit 200 based on the program stored in the above program storage (not illustrated). This also applies to examples other than Example 1 of the treatment sequence.

### Step S1

The wafer W whose both front surface and rear surface are hydrophobization treatment targets is first transferred into the treatment container C, for example, as illustrated in FIG. 3.

Specifically, the wafer W is moved by the external substrate transfer mechanism (not illustrated) to between the lid part 31 raised to the aforementioned second position and the hot plate 20. Thereafter, the raising and lowering pins 24 are raised, whereby the wafer W is delivered from the substrate transfer mechanism to the raising and lowering pins 24 and moved to a delivery position. Thereafter, the substrate transfer mechanism is retracted from the inside of the treatment container C. Further, the lid part 31 is lowered down to the aforementioned first position to form the treatment space S by the lid part 31 and the lower member 2.

In this event, the wafer W is supported on the raising and lowering pins 24 so that the center of the wafer W coincides with the center of the hot plate 20, namely, the center of the second supply port 91 in a predetermined allowable range.

### Step S2

Next, the supply of the hydrophobizing gas to the front surface of the wafer W and the supply of the hydrophobizing gas to the rear surface are performed. Specifically, the supplies of the hydrophobizing gas are performed at the same time.

More specifically, the wafer W supported on the raising and lowering pins 24 is moved to an upper treatment position above the gap pins 23. The upper treatment position is a position separated from the front surface of the hot plate 20 and the tops of the gap pins 23, and is, for example, a position 2 mm from the front surface of the hot plate 20.

In this state, as illustrated in FIG. 4, the supply of the hydrophobizing gas from the central supply port 42 toward a front surface central portion of the wafer W and the supply of the hydrophobizing gas from the second supply port 91 toward a rear surface central portion of the wafer W are performed. Note that no gas is supplied from the outer peripheral supply port 43. Further, the exhaust of the treatment space S via the upper outer peripheral exhaust port 121 and the exhaust of the treatment space S via the lateral exhaust port 122 are performed.

Thus, the hydrophobizing gas from the central supply port 42 flows from the center toward the outer side of the wafer W along the front surface of the wafer W, and the hydrophobizing gas from the second supply port 91 flows from the center toward the outer side of the wafer W along the rear surface of the wafer W. As a result of this, hydrophobic membranes are formed on the entire front surface and rear surface of the wafer W. Further, because the wafer W is separated from the hot plate 20 and is thus relatively low in temperature, physical adsorption of constituent molecules of the hydrophobic membranes can be promoted on the entire front surface and rear surface of the wafer W.

For example, after a lapse of a predetermined time after the start of the supply of the hydrophobizing gas, this Step S2 is ended.

At this Step S2, the exhaust via the upper outer peripheral exhaust port 121 and the exhaust via the lateral exhaust port 122 are performed in a manner, for example, that gas containing the hydrophobizing gas does not leak to the outside of the treatment container C and the atmosphere outside the treatment container C does not flow into the treatment space S. Specifically, the control is performed so as to satisfy the following Expressions (a), (b).

$$L 1 + L 2 < L 11 + L 12 \qquad ( a )$$

$$L 11 < L 12 \qquad ( b )$$

L1: supply flow rate of the hydrophobizing gas from the central supply port 42
L2: supply flow rate of the hydrophobizing gas from the second supply port 91
L11: exhaust flow rate via the upper outer peripheral exhaust port 121
L12: exhaust flow rate via the exhaust path 142 communicating with the lateral exhaust port 122

Further, at this Step S2, the exhaust via the upper outer peripheral exhaust port 121 and the exhaust via the lateral exhaust port 122 may be performed so as to satisfy the following Expression (c).

$$L 1 + L 2 > L 11 \qquad ( c )$$

If the exhaust flow rate via the upper outer peripheral exhaust port 121 is too high, the hydrophobizing gas is less likely to flow into a portion of the rear surface of the wafer W corresponding to the back of the raising and lowering pins 24 as viewed from the center of the wafer W to result in that the hydrophobic property on the rear surface of the wafer W becomes nonuniform within a plane, but this can be suppressed by satisfying the above Expression (c).

Further, at this Step S2, the exhaust via the upper outer peripheral exhaust port 121 and the exhaust via the lateral exhaust port 122 may be performed so as to satisfy the following Expression (d).

$$L 13 > L 11 \qquad ( d )$$

L13: exhaust flow rate from the treatment space S via the lateral exhaust port 122

By exhausting from both the upper outer peripheral exhaust port 121 close to the front surface side of the wafer W and the lateral exhaust port 122 close to the rear surface side of the wafer W, it is easy to inhibit both the hydrophobizing gas supplied to the front surface from flowing around to the rear surface (hereinafter, referred to as flowing around from the front surface to the rear surface) and the hydrophobizing gas supplied to the rear surface from flowing around to the front surface (hereinafter, referred to as flowing around from the rear surface to the front surface).

Note that during the treatment, a space height on the upper side of the wafer W is sometimes larger than a space height on the lower side of the wafer W. In this case, the flow velocity tends to be relatively higher on the side lower than on the upper side of the wafer W, and a gas flow at the high flow velocity formed on the lower side of the wafer W inhibits the flowing around from the front surface to the rear surface. The condition of L13>L11 in the above Expression (d) is a condition that the high flow velocity on the lower side of the wafer W is formed to promote the gas flow on the lower side of the wafer W, namely, the gas flow on the rear surface side to the lateral exhaust port 122 on the side lower than the upper outer peripheral exhaust port 121 in the case of the aforementioned space height relation. Therefore, this condition is considered to be preferable for both the flowing around from the front surface to the rear surface and the flowing around from the rear surface to the front surface.

Under a condition of L12>L13, the atmosphere outside the treatment container C is also sucked into the exhaust path 142 together with the gas in the treatment space S by the exhaust via the exhaust path 142, thus making it possible to inhibit the gas in the treatment space S from leaking to the outside of the treatment container C. In other words, under a condition of L12>L13>L11 in the case of the aforementioned space height relation, it is possible to inhibit the gas containing the hydrophobizing gas from leaking to the outside of the treatment container C and prevent the flowing around between the front side and the rear side of the wafer W. Note that an example of the configuration establishing the condition of L12>L13 is that a gap at the lateral exhaust port 122 is provided larger than gaps communicating with the exhaust path 142 and the space outside the treatment container C on the outside of the former gap.

### Step S3

Subsequently, heat treatments on the front surface and the rear surface of the wafer W are performed. Specifically, these heat treatments are performed at the same time.

More specifically, the supply of the hydrophobizing gas from the central supply port 42 toward the front surface central portion of the wafer W and the supply of the hydrophobizing gas from the second supply port 91 toward the rear surface central portion of the wafer W are stopped. Along with this, the raising and lowering pins 24 are lowered to mount the wafer W on the hot plate as illustrated in FIG. 5, that is, the wafer W is delivered from the raising and lowering pins 24 to the gap pins 23. Thus, the wafer W is heated, and the hydrophobic membranes formed on the front surface and the rear surface of the wafer W are heat-treated at a relatively high temperature, whereby chemical adsorption of the constituent molecules of the hydrophobic membranes on the front surface and the rear surface of the wafer W is promoted.

For example, after a lapse of a predetermined time after the wafer W is mounted on the hot plate 20, this Step S3 is ended.

Note that at this Step S3, the exhaust of the treatment space S via the upper outer peripheral exhaust port 121 and the exhaust of the treatment space S via the lateral exhaust port 122 are performed continuously from Step S2. Note that the inert gas is not supplied from the central supply port 42 and the second supply port 91, and no gas is supplied from the outer peripheral supply port 43.

Because the hydrophobizing gas and the inert gas are not supplied from the second supply port 91 to the rear surface of the wafer W during the heat treatment at this Step S3, it is possible to prevent the wafer W from floating from the hot plate 20.

### Step S4

Next, the atmosphere in the treatment container C is replaced with the inert gas.

Specifically, the raising and lowering pins 24 are raised, and the wafer W is delivered from the hot plate 20 to the raising and lowering pins 24 and moved to a replacement position above the gap pins 23. The replacement position may be the same as the aforementioned upper treatment position.

In this state, as illustrated in FIG. 6, the supply of the inert gas from the central supply port 42 toward the front surface central portion of the wafer W and the supply of the inert gas from the second supply port 91 toward the rear surface central portion of the wafer W are performed. Note that the supply of the inert gas from the outer peripheral supply port 43 is not performed in this example, but may be performed. Further, the exhaust of the treatment space S via the upper outer peripheral exhaust port 121 and the exhaust of the treatment space S via the lateral exhaust port 122 are performed continuously from Step S2 and Step S3.

Thus, the hydrophobizing gas in the treatment space S is replaced with the inert gas. If the wafer W is moved to the replacement position and separated from the hot plate 20 (specifically, the gap pins 23) as explained above during the replacement, it is possible to inhibit the hydrophobizing gas near the rear surface of the wafer W from remaining in the treatment container C at the replacement.

For example, after a lapse of a predetermined time after the start of the supply of the inert gas, this Step S4 is ended.

Note that the sum of a supply flow rate L21 of the inert gas from the central supply port 42 and a supply flow rate L22 of the inert gas from the second supply port 91 at this Step S4 may be made equal to or less than the sum of the supply flow rate L1 of the hydrophobizing gas from the central supply port 42 and the supply flow rate L2 of the hydrophobizing gas from the second supply port 91 at Step S2. In other words, it may be set that L21+L22≤L1+L2. This can inhibit the gas containing the hydrophobizing gas from leaking to the outside of the treatment container C even without changing at Step S4 the sum of the exhaust flow rate L11 via the upper outer peripheral exhaust port 121 and the exhaust flow rate 12 via the exhaust path 142 communicating with the lateral exhaust port 122 (L11+L12) from that at Step S2.

Besides, in the case of L21+L22>L1+L2, it is necessary to make L11+L12 higher than that at Step S2 in order to inhibit the gas containing the hydrophobizing gas from leaking to the outside of the treatment container C at Step S4, but it is possible to improve the replacement efficiency of the atmosphere in the treatment container C. In other words, by making the total supply flow rate and the total exhaust flow rate of the inert gas higher at Step S4 than at Step S2, it is possible to improve the replacement efficiency of the atmosphere in the treatment container C. In this case, by increasing the total exhaust flow rate and then increasing the total supply flow rate of the inert gas, it is possible to inhibit the gas containing the hydrophobizing gas from leaking to the outside of the treatment container C.

### Step S5

Then, the wafer W is transferred out of the treatment container C.

Specifically, for example, the supply of the inert gas from the central supply port 42 toward the front surface central portion of the wafer W and the supply of the inert gas from the second supply port 91 toward the rear surface central portion of the wafer W are stopped, and then the exhaust of the treatment space S via the upper outer peripheral exhaust port 121 and the exhaust of the treatment space S via the lateral exhaust port 122 are also stopped. Then, the lid part 31 is raised up to the aforementioned second position and the raising and lowering pins 24 are raised, and the wafer W is raised in a state of being supported on the raising and lowering pins 24 up to the delivery position. Subsequently, the substrate transfer mechanism is inserted into the treatment container C to between the lid part 31 and the hot plate 20, and then the raising and lowering pins 24 are lowered to deliver the wafer W to the substrate transfer mechanism. Thereafter, the substrate transfer mechanism is retracted from the inside of the treatment container C, whereby the wafer W is transferred out of the treatment container C.

With the above, a serial treatment sequence is completed.

According to Example 1 of the treatment sequence, the wafer W is low in temperature during the supply of the hydrophobizing gas to the front surface as compared with later-explained Example 2 of the treatment sequence and so on, so that a physical adsorption amount of constituent molecules of the hydrophobic membrane to the wafer front surface is large. Accordingly, a contact angle of the hydrophobic membrane on the front surface of the wafer W can be made large.

Note that the purpose of forming the hydrophobic membrane on the front surface of the wafer is, for example, to increase the adhesion between a later-formed resist film and the wafer W. Another purpose of forming the hydrophobic membrane on the rear surface of the wafer W is, for example, to improve the overlay during the exposure as explained above by the friction reducing film as the hydrophobic membrane.

### Example 2 of the Treatment Sequence

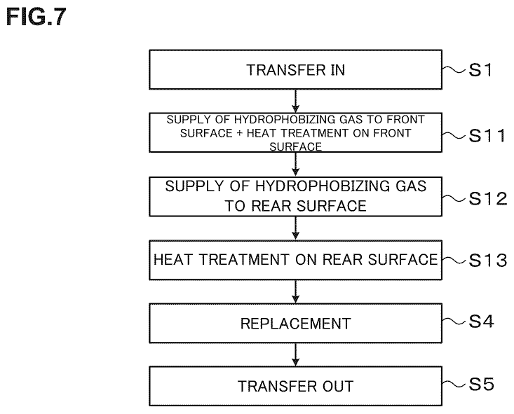

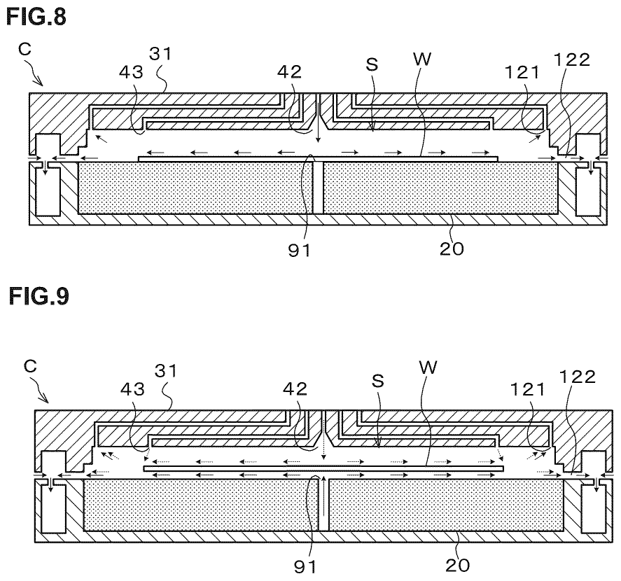

FIG. 7 is a flowchart illustrating main steps of Example 2 of the treatment sequence. FIG. 8 and FIG. 9 are views illustrating the states of the treatment container C during the execution of Example 2 of the treatment sequence.

Example 2 of the treatment sequence is applied to a wafer W whose both front surface and rear surface are hydrophobization treatment targets as in Example 1 of the treatment sequence. However, though the supply of the hydrophobizing gas to the front surface of the wafer W and the supply of the hydrophobizing gas to the rear surface are performed at the same time in Example 1 of the treatment sequence, the supplies are performed in order in Example 2 of the treatment sequence, and specifically, the supply of the hydrophobizing gas to the front surface of the wafer W and the supply of the hydrophobizing gas to the rear surface are performed in this order. Hereinafter, this will be explained more specifically.

### Step S11

In Example 2 of the treatment sequence, as illustrated in FIG. 7, after Step S1, the supply of the hydrophobizing gas to the front surface of the wafer W and the heat treatment on the front surface of the wafer W are performed. Specifically, they are performed at the same time.

More specifically, the raising and lowering pins 24 are lowered to mount the wafer W on the hot plate 20 as illustrated in FIG. 8, that is, the wafer W is delivered from the raising and lowering pins 24 to the gap pins 23. Further, the supply of the hydrophobizing gas from the central supply port 42 toward the front surface central portion of the wafer W is performed. Note that no gas is supplied from the second supply port 91 and the outer peripheral supply port 43. Further, the exhaust of the treatment space S via the upper outer peripheral exhaust port 121 and the exhaust of the treatment space S via the lateral exhaust port 122 are performed.

Thus, the hydrophobizing gas from the central supply port 42 flows from the center toward the outer side of the wafer W along the front surface of the wafer W. As a result of this, a hydrophobic membrane is formed on the entire front surface of the wafer W.

Further, the wafer W is heated by the hot plate 20, whereby the hydrophobic membrane formed on the front surface of the wafer W is heat-treated.

For example, after a lapse of a predetermined time after the wafer W is mounted on the hot plate 20 and the supply of the hydrophobizing gas is started, this Step S11 is ended.

### Step S12

Next, the supply of the hydrophobizing gas to the rear surface of the wafer W is performed.

Specifically, the raising and lowering pins 24 are raised, and the wafer W is delivered from the hot plate 20 to the raising and lowering pins 24 and moved to the aforementioned upper treatment position.

In this state, as illustrated in FIG. 9, the supply of the hydrophobizing gas from the second supply port 91 toward the rear surface central portion of the wafer W is performed. Further, the exhaust of the treatment space S via the upper outer peripheral exhaust port 121 and the exhaust of the treatment space S via the lateral exhaust port 122 are performed.

Thus, the hydrophobizing gas from the second supply port 91 flows from the center toward the outer side of the wafer W along the rear surface of the wafer W. As a result of this, a hydrophobic membrane is formed on the entire rear surface of the wafer W.

Further, the supply of the inert gas from the central supply port 42 toward the front surface central portion of the wafer W and the supply of the inert gas from the outer peripheral supply port 43 toward a front surface outer peripheral portion of the wafer W are performed. This makes it possible to inhibit the hydrophobizing gas supplied to the rear surface of the wafer W from flowing around to the front surface of the wafer W.

Note that the hydrophobizing gas is not supplied from the central supply port 42 and the outer peripheral supply port 43.

At this Step S12, the exhaust via the upper outer peripheral exhaust port 121 and the exhaust via the lateral exhaust port 122 are performed, for example, in a manner that the gas containing the hydrophobizing gas does not leak to the outside of the treatment container C and the atmosphere outside the treatment container C does not flow into the treatment space S. Specifically, the control is performed so as to satisfy the above Expression (b) and the following Expression (e).

$$L 21 + L 23 + L 2 < L 11 + L 12 \qquad ( e )$$

L23: supply flow rate of the inert gas from the outer peripheral supply port 43

Further, at this Step S12, the exhaust via the upper outer peripheral exhaust port 121 and the exhaust via the lateral exhaust port 122 may be performed so as to satisfy the following Expression (f).

$$L 21 + L 23 + L 2 > L 11 \qquad ( f )$$

If the exhaust flow rate via the upper outer peripheral exhaust port 121 is too high, the hydrophobizing gas is less likely to flow into a portion of the rear surface of the wafer W corresponding to the back of the raising and lowering pins 24 as viewed from the center of the wafer W to result in that the hydrophobic property on the rear surface of the wafer W becomes nonuniform within a plane, but this can be inhibited by satisfying the above Expression (f).

Note that also at this Step S12, the exhaust via the upper outer peripheral exhaust port 121 and the exhaust via the lateral exhaust port 122 may be performed so as to satisfy the above Expression (d) as at the above Step S2.

### Step S13

Subsequently, a heat treatment on the rear surface of the wafer W is performed. Specifically, the heat treatment on the rear surface of the wafer W and a reheat treatment on the front surface of the wafer W are performed at the same time.

More specifically, the supply of the hydrophobizing gas from the second supply port 91 toward the rear surface central portion of the wafer W, the supply of the inert gas from the central supply port 42 toward the front surface central portion of the wafer W, and the supply of the inert gas from the outer peripheral supply port 43 toward the front surface outer peripheral portion of the wafer W are stopped. Along with this, the raising and lowering pins 24 are lowered to mount the wafer W on the hot plate 20 as illustrated in FIG. 5, that is, the wafer W is delivered from the raising and lowering pins 24 to the gap pins 23. Thus, the wafer W is heated, the hydrophobic membrane formed on the rear surface of the wafer W is heat-treated, and the hydrophobic membrane formed on the front surface of the wafer W is reheat-treated.

For example, after a lapse of a predetermined time after the wafer W is mounted on the hot plate 20, this Step S13 is ended.

Note that at this Step S13, the exhaust of the treatment space S via the upper outer peripheral exhaust port 121 and the exhaust of the treatment space S via the lateral exhaust port 122 are performed continuously from Step S12. Note that no gas is supplied from the central supply port 42 and the outer peripheral supply port 43.

Thereafter, Step S4 and Step 5 are performed as in Example 1 of the treatment sequence.

### Example 3 of the Treatment Sequence

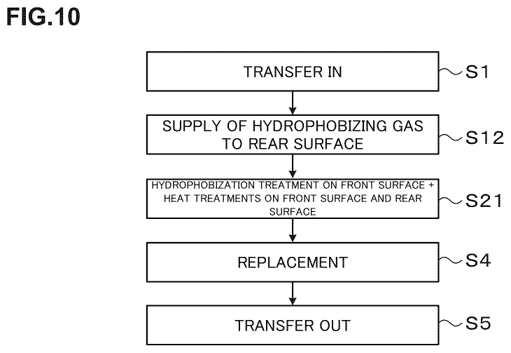

FIG. 10 is a flowchart illustrating main steps of Example 3 of the treatment sequence.

In Example 3 of the treatment sequence, the supply of the hydrophobizing gas to the front surface of the wafer W and the supply of the hydrophobizing gas to the rear surface are performed in order as in Example 2 of the treatment sequence. However, in Example 3 of the treatment sequence, the supply of the hydrophobizing gas to the rear surface of the wafer W and the supply of the hydrophobizing gas to the front surface are performed in this order unlike Example 2 of the treatment sequence. Hereinafter, this will be explained more specifically.

### Step S21

In Example 3 of the treatment sequence, as illustrated in FIG. 10, after Step S1, Step S12 in Example 2 of the treatment sequence is performed, that is, the supply of the hydrophobizing gas to the rear surface of the wafer W is performed. Thereafter, the supply of the hydrophobizing gas to the front surface of the wafer W and the heat treatments on the front surface and the rear surface of the wafer W are performed. Specifically, they are performed at the same time.

More specifically, the raising and lowering pins 24 are lowered to mount the wafer W on the hot plate 20, that is, the wafer W is delivered from the raising and lowering pins 24 to the gap pins 23. Further, as in FIG. 8, the supply of the hydrophobizing gas from the central supply port 42 toward the front surface central portion of the wafer W is performed. Specifically, the supply of the hydrophobizing gas from the second supply port 91, the supply of the inert gas from the central supply port 42, and the supply of the inert gas from the outer peripheral supply port 43 which are performed at Step S12 are stopped, and the supply of the hydrophobizing gas from the central supply port 42 toward the front surface central portion of the wafer W is performed. Further, the exhaust of the treatment space S via the upper outer peripheral exhaust port 121 and the exhaust of the treatment space S via the lateral exhaust port 122 are performed continuously from Step S12.

Thus, the hydrophobizing gas from the central supply port 42 flows from the center toward the outer side of the wafer W along the front surface of the wafer W. As a result of this, a hydrophobic membrane is formed on the entire front surface of the wafer W.

Further, the wafer W is heated by the hot plate 20, whereby the hydrophobic membranes formed on the front surface and the rear surface of the wafer W are heat-treated.

For example, after a lapse of a predetermined time after the wafer W is mounted on the hot plate 20 and the supply of the hydrophobizing gas is started, this Step S21 is ended.

Thereafter, Step S4 and Step 5 are performed as in Example 1 of the treatment sequence.

According to Example 3 of the treatment sequence, the number of steps is small as compared with Example 2 of the treatment sequence, so that it is possible to reduce the time required to hydrophobize both the front surface and the rear surface of the wafer W. Further, the hydrophobization treatment on the front surface of the wafer W is performed as in the existing apparatus which performs the hydrophobization treatment on only the front surface, so that the findings obtained using the above existing apparatus can be used for the adjustment of the hydrophobization treatment condition for the front surface where uniformity and so on are more important. In other words, regarding the hydrophobization treatment on the front surface of the wafer W, this treatment sequence is highly compatible with respect to the above existing apparatus.

At the time when the supply of the hydrophobizing gas from the central supply port 42 toward the front surface central portion of the wafer W at Step S21, the following may be performed. Specifically, the supply of the hydrophobizing gas from the second supply port 91 performed at Step S12 is stopped, then the supply of the inert gas from the central supply port 42 performed also at the same Step S12 is stopped, thereafter the supply of the hydrophobizing gas from the central supply port 42 may be started, and the supply of the inert gas from the outer peripheral supply port 43 may be stopped. This can more surely inhibit the hydrophobizing gas supplied from the central supply port 42 to the front surface of the wafer W from flowing around to the rear surface of the wafer W.

### Example 4 of the Treatment Sequence

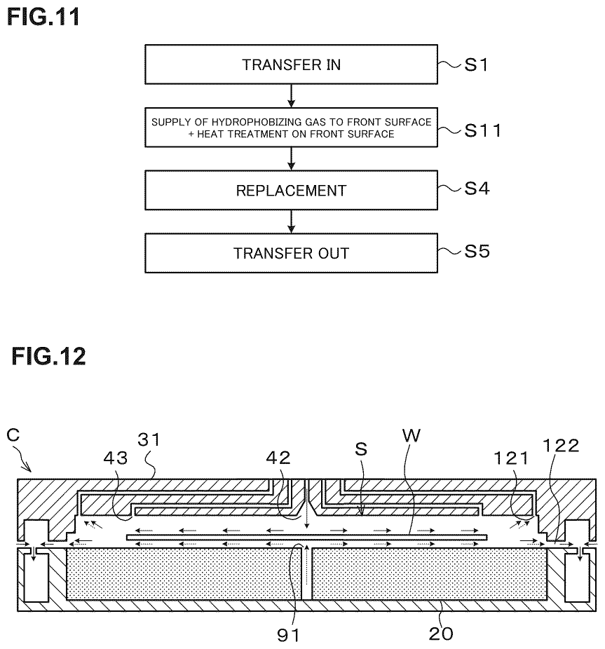

FIG. 11 is a flowchart illustrating main steps of Example 4 of the treatment sequence.

Example 4 of the treatment sequence is applied to a wafer W whose only front surface is a hydrophobization treatment target unlike Example 1 of the treatment sequence.

In Example 4 of the treatment sequence, as illustrated in FIG. 11, after Step S1, Step S11 is performed, that is, the supply of the hydrophobizing gas to the front surface of the wafer W and the heat treatment on the front surface of the wafer W are performed. Specifically, they are performed at the same time after Step S1.

Thereafter, Step S4 and Step S5 are performed.

This treatment sequence is highly compatible with respect to the existing apparatus which performs the hydrophobization treatment on only the front surface of the wafer W.

### Modification 1 of Example 4 of the Treatment Sequence

FIG. 12 is a view for explaining Modification 1 of Example 4 of the treatment sequence.

Though the supply of the hydrophobizing gas to the front surface of the wafer W and the heat treatment on the front surface of the wafer W are performed at the same time in the above Example 4 of the treatment sequence, the heat treatment on the front surface of the wafer W may be performed after the supply of the hydrophobizing gas to the front surface of the wafer W.

In this case, for example, in a state where the wafer W supported on the raising and lowering pins 24 is moved to the aforementioned upper treatment position, the supply of the hydrophobizing gas from the central supply port 42 toward the front surface central portion of the wafer W is performed as illustrated in FIG. 12. Further, the exhaust of the treatment space S via the upper outer peripheral exhaust port 121 and the exhaust of the treatment space S via the lateral exhaust port 122 are performed.

Thus, the hydrophobizing gas from the central supply port 42 flows from the center toward the outer side of the wafer W along the front surface of the wafer W. As a result of this, a hydrophobic membrane is formed on the entire front surface of the wafer W.

Further, the supply of the inert gas from the second supply port 91 toward the rear surface central portion of the wafer W is performed. This makes it possible to inhibit the hydrophobizing gas supplied to the front surface of the wafer W from flowing around to the rear surface of the wafer W.

Note that the hydrophobizing gas is not supplied from the second supply port 91 and no gas is supplied from the outer peripheral supply port 43.

In this event, the exhaust via the upper outer peripheral exhaust port 121 and the exhaust via the lateral exhaust port 122 are performed, for example, in a manner that the gas containing the hydrophobizing gas does not leak to the outside of the treatment container C and the atmosphere outside the treatment container C does not flow into the treatment space S. Specifically, the control is performed so as to satisfy the above Expression (b) and the following Expression (g).

$$L 1 + L 22 < L 11 + L 12 \qquad ( g )$$

For example, after a lapse of a predetermined time after the start of the supply of the hydrophobizing gas, this hydrophobizing gas supply step is ended.

Thereafter, the supply of the hydrophobizing gas from the central supply port 42 toward the front surface central portion of the wafer W and the supply of the inert gas from the second supply port 91 toward the rear surface central portion of the wafer W are stopped. Along with this, the raising and lowering pins 24 are lowered to mount the wafer W on the hot plate 20 as in FIG. 5, that is, the wafer W is delivered from the raising and lowering pins 24 to the gap pins 23. Thus, the wafer W is heated and the hydrophobic membrane formed on the front surface of the wafer W is heat-treated.

For example, after a lapse of a predetermined time after the wafer W is mounted on the hot plate 20, this heat treatment step is ended.

In this modification, because the wafer W is low in temperature during the supply of the hydrophobizing gas to the front surface as compared with Example 4 of the treatment sequence, the physical adsorption amount of constituent molecules of the hydrophobic membrane to the wafer front surface is large. Further, since the wafer W is close to the central supply port 42 during the supply of the hydrophobizing gas to the front surface as compared with Example 4 of the treatment sequence, the hydrophobizing gas is strongly sprayed to the wafer W. Thus, the contact angle of the hydrophobic membrane on the front surface of the wafer W can be made large. Further, since the inert gas is supplied to the rear surface during the supply of the hydrophobizing gas to the front surface, it is possible to more surely inhibit the hydrophobizing gas from flowing around to the rear surface as compared with Example 4 of the treatment sequence.

### Example 5 of the Treatment Sequence

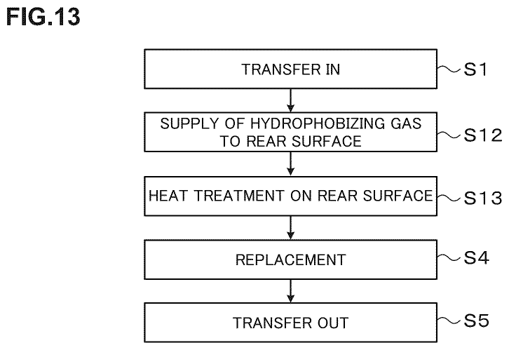

FIG. 13 is a flowchart illustrating main steps of Example 5 of the treatment sequence.

Example 5 of the treatment sequence is applied to a wafer W whose only rear surface is a hydrophobization treatment target unlike Example 1 of the treatment sequence and so on.

In Example 5 of the treatment sequence, as illustrated in FIG. 13, subsequently to Step S1, Step S12 and Step S13 are performed, that is, the supply of the hydrophobizing gas to the rear surface of the wafer W and the heat treatment on the rear surface of the wafer W are performed. Specifically, after Step S1, the supply of the hydrophobizing gas to the rear surface of the wafer W and the heat treatment on the rear surface of the wafer W are performed in order.

Thereafter, Step S4 and Step S5 are performed.

### Modification 2 of Example 4 of the Treatment Sequence

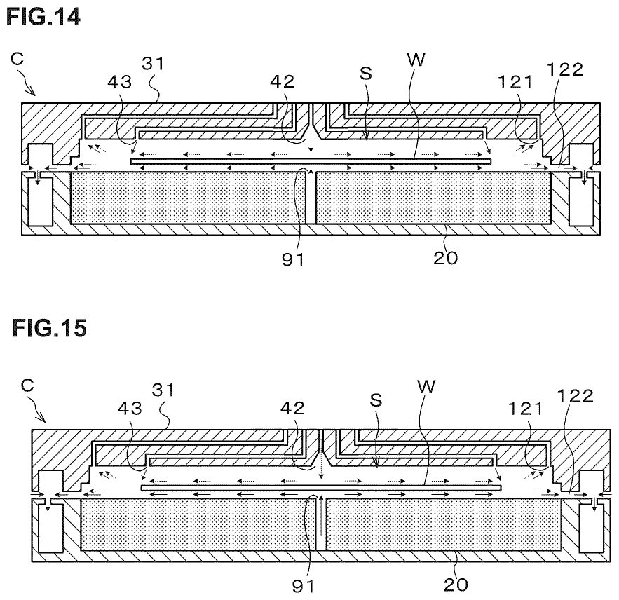

FIG. 14 is a view for explaining Modification 2 of Example 4 of the treatment sequence.

In the above Example 4 of the treatment sequence and Modification 1 thereof, when performing the hydrophobization treatment on only the front surface of the wafer W, the hydrophobization treatment is performed on the entire front surface, that is, the hydrophobic membrane is formed on the entire front surface. Instead of this, when performing the hydrophobization treatment on only the front surface of the wafer W, the hydrophobization treatment may be performed on only an outer peripheral portion of the front surface, that is, the hydrophobic membrane may be formed on only the outer peripheral portion of the front surface.

In this case, for example, in a state where the wafer W supported on the raising and lowering pins 24 is moved to the aforementioned upper treatment position, the supply of the hydrophobizing gas from the outer peripheral supply port 43 toward the front surface outer peripheral portion of the wafer W is performed as illustrated in FIG. 14. Further, the exhaust of the treatment space S via the upper outer peripheral exhaust port 121 and the exhaust of the treatment space S via the lateral exhaust port 122 are performed.

Thus, the hydrophobizing gas from the outer peripheral supply port 43 flows toward the outer side of the wafer W along the front surface of the wafer W. As a result of this, a hydrophobic membrane is formed on the front surface outer peripheral portion (including a bevel portion) of the wafer W.

Further, the supply of the inert gas from the central supply port 42 toward the front surface central portion of the wafer W is performed. This supply of the inert gas and the above exhaust make the inert gas flow from the center toward the outer side of the wafer W along the front surface of the wafer W, thus making it possible to inhibit the hydrophobizing gas from adhering to the inner side of the front surface outer peripheral portion.

Further, the supply of the inert gas from the second supply port 91 toward the rear surface central portion of the wafer W is performed. This supply of the inert gas and the above exhaust make the inert gas flow from the center toward the outer side of the wafer W along the rear surface of the wafer W, thus making it possible to inhibit the hydrophobizing gas supplied to the front surface of the wafer W from flowing around to the rear surface of the wafer W.

For example, after a lapse of a predetermined time after the start of the supply of the hydrophobizing gas, this hydrophobizing gas supply step is ended.

Thereafter, the supply of the hydrophobizing gas from the outer peripheral supply port 43 toward the front surface outer peripheral portion of the wafer W, the supply of the inert gas from the central supply port 42 toward the front surface central portion of the wafer W, and the supply of the inert gas from the second supply port 91 toward the rear surface central portion of the wafer W are stopped. Along with this, the raising and lowering pins 24 are lowered to mount the wafer W on the hot plate 20 as in FIG. 5, that is, the wafer W is delivered from the raising and lowering pins 24 to the gap pins 23. Thus, the wafer W is heated and the hydrophobic membrane formed on the front surface outer peripheral portion of the wafer W is heat-treated.

For example, after a lapse of a predetermined time after the wafer W is mounted on the hot plate 20, this heat treatment step is ended.

By performing the hydrophobization treatment on only the outer peripheral portion of the front surface of the wafer W as in this modification, even if, for example, water exists on a stage of a liquid immersion exposure apparatus on which the wafer W is to be mounted, it is possible to inhibit the water from flowing around to the rear surface of the wafer W to cause defects.

### Modification of Example 1 of the Treatment Sequence

FIG. 15 is a view for explaining a modification of Example 1 of the treatment sequence.

In the above Example 1 of the treatment sequence, when performing the hydrophobization treatment on both the front surface and the rear surface of the wafer W, the hydrophobization treatment is performed on the entire front surface, that is, the hydrophobic membrane is formed on the entire surface. Instead of this, when performing the hydrophobization treatment on both the front surface and the rear surface of the wafer W, the hydrophobization treatment may be performed on only the outer peripheral portion of the front surface, that is, the hydrophobic membrane may be formed on only the outer peripheral portion of the front surface.

In this case, for example, in a state where the wafer W supported on the raising and lowering pins 24 is moved to the aforementioned upper treatment position, the supply of the hydrophobizing gas from the outer peripheral supply port 43 toward the front surface outer peripheral portion of the wafer W and the supply of the hydrophobizing gas from the second supply port 91 toward the rear surface central portion of the wafer W are performed as illustrated in FIG. 15. Further, the exhaust of the treatment space S via the upper outer peripheral exhaust port 121 and the exhaust of the treatment space S via the lateral exhaust port 122 are performed.

Thus, the hydrophobizing gas from the outer peripheral supply port 43 flows toward the outer side of the wafer W along the front surface of the wafer W and the hydrophobizing gas from the second supply port 91 flows from the center toward the outer side of the wafer W along the rear surface of the wafer W. As a result of this, the hydrophobic membrane is formed on the front surface outer peripheral portion of the wafer W and the hydrophobic membrane is formed on the entire rear surface of the wafer W.

Further, the supply of the inert gas from the central supply port 42 toward the front surface central portion of the wafer W is performed. This supply of the inert gas and the above exhaust make the inert gas flow from the center toward the outer side of the wafer W along the front surface of the wafer W, thus making it possible to inhibit the hydrophobizing gas from adhering to the inner side of the front surface outer peripheral portion.

For example, after a lapse of a predetermined time after the start of the supply of the hydrophobizing gas, this hydrophobizing gas supply step is ended.

Thereafter, the supply of the hydrophobizing gas from the outer peripheral supply port 43 toward the front surface outer peripheral portion of the wafer W, the supply of the hydrophobizing gas from the second supply port 91 toward the rear surface central portion of the wafer W, and the supply of the inert gas from the central supply port 42 toward the front surface central portion of the wafer W are stopped. Along with this, the raising and lowering pins 24 are lowered to mount the wafer W on the hot plate 20 as in FIG. 5, that is, the wafer W is delivered from the raising and lowering pins 24 to the gap pins 23. Thus, the wafer W is heated and the hydrophobic membranes formed on the front surface outer peripheral portion and the entire rear surface of the wafer W are heat-treated.

For example, after a lapse of a predetermined time after the wafer W is mounted on the hot plate 20, this heat treatment step is ended.

Also in this modification, even if, for example, water exists on the stage of the liquid immersion exposure apparatus on which the wafer W is to be mounted as in Modification 2 of Example 4 of the treatment sequence, it is possible to inhibit the water from flowing around to the rear surface of the wafer W to cause defects.

Note that the supply of the hydrophobizing gas to the front surface outer peripheral portion of the wafer W may be performed after the supply of the hydrophobizing gas to the rear surface of the wafer W. In this case, the height of the wafer W during the supply of the hydrophobizing gas to the front surface outer peripheral portion of the wafer W may be made higher than the height of the wafer W during the supply of the hydrophobizing gas to the rear surface of the wafer W to be closer to the outer peripheral supply port 43. This narrows a range in which the hydrophobizing gas supplied from the outer peripheral supply port 43 diffuses until reaching the front surface outer peripheral portion of the wafer W, so that a portion which the hydrophobizing gas well hits and a portion which the hydrophobizing gas is less likely to hit on the front surface of the wafer W become clearer. This makes it possible to more precisely control a range where the hydrophobic membrane is to be formed at the front surface outer peripheral portion of the wafer W.

### Another Modification of Example 1 of the Treatment Sequence

During the heat treatment on the front surface and the rear surface of the wafer at Step S3, the supply of the hydrophobizing gas toward the front surface central portion is stopped in the above example. Instead of this, the supply of the hydrophobizing gas toward the front surface central portion may be continued. This can further promote the hydrophobization on the front surface side of the wafer W.

Further, during the heat treatment on the front surface and the rear surface of the wafer at Step S3, the supply of the hydrophobizing gas toward the rear surface central portion is also stopped in the above example. Instead of this, the supply of the hydrophobizing gas toward the rear surface central portion may be performed at a low flow rate at which the wafer W does not float from the hot plate 20. This can further promote the hydrophobization on the rear surface side of the wafer W.

### Main Effects of the Embodiment

As explained above, according to the embodiment, it is possible to perform the hydrophobization treatment on both the front surface and the rear surface of the wafer W.

Further, by the hydrophobization treatment apparatus 1 and the hydrophobization treatment method capable of performing the hydrophobization treatment on both the front surface and the rear surface of the wafer W according to the embodiment, not only the wafer W whose both front surface and rear surface are hydrophobization treatment targets but also the wafer W whose only front surface or rear surface is a hydrophobization treatment target can be treated.

Further, according to the embodiment, it is possible to perform the hydrophobization treatment on only the outer peripheral portion of the front surface of the wafer W.

### Other Modifications

During the supply of the hydrophobizing gas to the front surface of the wafer W, the hydrophobizing gas may be supplied from the central supply port 42 and the inert gas may be supplied from the outer peripheral supply port 43. This makes it possible to form the hydrophobic membrane in only a region of the front surface of the wafer W except for the outer peripheral portion.

The embodiments disclosed herein are examples in all respects and should not be considered to be restrictive. Various omissions, substitutions, and changes may be made in the embodiments without departing from the scope and spirit of the attached claims. For example, configuration requirements of the above embodiments can be arbitrarily combined. The operations and effects about the configuration requirements relating to an arbitrary combination can be obtained as a matter of course from the combination, and those skilled in the art can obtain clear other operations and other effects from the description herein.

Besides, the effects explained herein are merely explanatory or illustrative in all respects and not restrictive. The technique relating to this disclosure can offer other clear effects to those skilled in the art from the description herein in addition to or in place of the above effects.

Note that the following configuration examples also belong to the technical scope of this disclosure.
(1) A hydrophobization treatment apparatus performing a hydrophobization treatment on a substrate, including:
   a treatment container configured to house the substrate and form a treatment space;
   a first supply port configured to supply first gas from above the substrate in the treatment container to the substrate; and
   a second supply port configured to supply second gas from a position facing a central region of the substrate below the substrate in the treatment container to the substrate,
   the hydrophobization treatment apparatus being configured to be able to supply a hydrophobizing gas as the first gas from the first supply port and the second gas from the second supply port.
(2) The hydrophobization treatment apparatus according to the (1), wherein:
   the first supply port has a central supply port formed at a position facing the second supply port across the substrate in the treatment container; and
   for the substrate whose both front surface and rear surface are hydrophobization treatment targets, the hydrophobizing gas as the first gas is supplied from the central supply port during the hydrophobization treatment on the front surface.
(3) The hydrophobization treatment apparatus according to the (2), wherein
   for the substrate whose both the front surface and the rear surface are the hydrophobization treatment targets, the hydrophobizing gas is supplied to the front surface and the rear surface at a same time.
(4) The hydrophobization treatment apparatus according to the (2), wherein
   for the substrate whose both the front surface and the rear surface are the hydrophobization treatment targets, the supply of the hydrophobizing gas to the front surface and the supply of the hydrophobizing gas to the rear surface are performed in order.
(5) The hydrophobization treatment apparatus according to the (1), wherein:
   the first supply port has a central supply port formed at a position facing the second supply port across the substrate in the treatment container; and
   for the substrate whose only front surface is a hydrophobization treatment target, the hydrophobizing gas as the first gas is supplied from the central supply port and an inert gas is supplied as the second gas from the second supply port during the hydrophobization treatment on the front surface.
(6) The hydrophobization treatment apparatus according to any one of the (1) to (5), further including
   an upper outer peripheral exhaust port provided above and outside the substrate in the treatment container and opening to the treatment space, wherein
   when the hydrophobizing gas is supplied into the treatment container, an inside of the treatment container is exhausted from the upper outer peripheral exhaust port.
(7) The hydrophobization treatment apparatus according to the (1), wherein
   the treatment container is configured such that an inside thereof is exhaustable from an exhaust position outside the substrate;
   the first supply port has:
      a central supply port formed at a position facing the second supply port across the substrate in the treatment container; and
      an outer peripheral supply port formed at a position between the central supply port and the outside exhaust position; and
   when a hydrophobization treatment is performed on only an outer peripheral portion of the front surface of the substrate in the treatment container, an inert gas as the first gas is supplied from the central supply port and the hydrophobizing gas is supplied as the first gas from the outer peripheral supply port.
(8) A hydrophobization treatment method for performing a hydrophobization treatment on a substrate, including
   selectively supplying a hydrophobizing gas from at least one of a first supply port provided above the substrate in a treatment container forming a treatment space and a second supply port provided at a position facing a central region of the substrate below the substrate in the treatment container.
(9) The hydrophobization treatment method according to the (8), wherein:
   the first supply port has a central supply port formed at a position facing the second supply port across the substrate in the treatment container; and
   at the selectively supplying the hydrophobizing gas, for the substrate whose both front surface and rear surface are hydrophobization treatment targets, the hydrophobizing gas to the front surface is supplied from the central supply port.
(10) The hydrophobization treatment method according to the (9), wherein
   at the selectively supplying the hydrophobizing gas, for the substrate whose both the front surface and the rear surface are the hydrophobization treatment targets, the hydrophobizing gas is supplied to the front surface and the rear surface at a same time.
(11) The hydrophobization treatment method according to the (9), wherein
   at the selectively supplying the hydrophobizing gas, for the substrate whose both the front surface and the rear surface are the hydrophobization treatment targets, the supply of the hydrophobizing gas to the front surface and the supply of the hydrophobizing gas to the rear surface are performed in order.
(12) The hydrophobization treatment method according to the (8), wherein:
   the first supply port has a central supply port formed at a position facing the second supply port across the substrate in the treatment container; and
   at the selectively supplying the hydrophobizing gas, for the substrate whose only front surface is a hydrophobization treatment target, the hydrophobizing gas is supplied from the central supply port and an inert gas is supplied from the second supply port.
(13) The hydrophobization treatment method according to any one of the (8) to (12), wherein:
   at the selectively supplying the hydrophobizing gas, an inside of the treatment container is exhausted from an upper outer peripheral exhaust port;
   and the upper outer peripheral exhaust port is provided above and outside the substrate in the treatment container and opens to the treatment space.
(14) The hydrophobization treatment method according to the (8), wherein
   the treatment container is configured such that an inside thereof is exhaustable from an exhaust position outside the substrate;
   the first supply port has:
      a central supply port formed at a position facing the second supply port across the substrate in the treatment container; and
      an outer peripheral supply port formed at a position between the central supply port and the outside exhaust position; and
   at the selectively supplying the hydrophobizing gas, for the substrate whose only outer peripheral portion of the front surface of the substrate is a hydrophobization treatment target, an inert gas is supplied from the central supply port and the hydrophobizing gas is supplied from the outer peripheral supply port.
(15) A computer-readable storage medium storing a program running on a computer of a control unit for controlling a hydrophobization treatment apparatus to cause the hydrophobization treatment apparatus to execute a hydrophobization treatment method for performing a hydrophobization treatment on a substrate,
   the hydrophobization treatment method including selectively supplying a hydrophobizing gas from at least one of a first supply port provided above the substrate in a treatment container forming a treatment space and a second supply port provided at a position facing a central region of the substrate below the substrate in the treatment container.
(16) A hydrophobization treatment method, including
   selectively performing a hydrophobization treatment of a front surface of a substrate or a hydrophobization treatment of a rear surface of the substrate according to a hydrophobization treatment target.

According to this disclosure, it is possible to perform a hydrophobization treatment on both a front surface and a rear surface of a substrate.

What is claimed is:

1. A hydrophobization treatment apparatus performing a hydrophobization treatment on a substrate, comprising:
a treatment container configured to house the substrate and form a treatment space;
a first supply port configured to supply first gas from above the substrate in the treatment container to the substrate; and
a second supply port configured to supply second gas from a position facing a central region of the substrate below the substrate in the treatment container to the substrate,
the hydrophobization treatment apparatus being configured to be able to supply a hydrophobizing gas as the first gas from the first supply port and the second gas from the second supply port.

2. The hydrophobization treatment apparatus according to claim 1, wherein:
the first supply port has a central supply port formed at a position facing the second supply port across the substrate in the treatment container; and
for the substrate whose both front surface and rear surface are hydrophobization treatment targets, the hydrophobizing gas as the first gas is supplied from the central supply port during the hydrophobization treatment on the front surface.

3. The hydrophobization treatment apparatus according to claim 2, wherein
for the substrate whose both the front surface and the rear surface are the hydrophobization treatment targets, the hydrophobizing gas is supplied to the front surface and the rear surface at a same time.

4. The hydrophobization treatment apparatus according to claim 2, wherein
for the substrate whose both the front surface and the rear surface are the hydrophobization treatment targets, the supply of the hydrophobizing gas to the front surface and the supply of the hydrophobizing gas to the rear surface are performed in order.

5. The hydrophobization treatment apparatus according to claim 1, wherein:
the first supply port has a central supply port formed at a position facing the second supply port across the substrate in the treatment container; and
for the substrate whose only front surface is a hydrophobization treatment target, the hydrophobizing gas as the first gas is supplied from the central supply port and an inert gas is supplied as the second gas from the second supply port during the hydrophobization treatment on the front surface.

6. The hydrophobization treatment apparatus according to claim 1, further comprising
an upper outer peripheral exhaust port provided above and outside the substrate in the treatment container and opening to the treatment space, wherein
when the hydrophobizing gas is supplied into the treatment container, an inside of the treatment container is exhausted from the upper outer peripheral exhaust port.

7. The hydrophobization treatment apparatus according to claim 1, wherein
the treatment container is configured such that an inside thereof is exhaustable from an exhaust position outside the substrate;
the first supply port has:
a central supply port formed at a position facing the second supply port across the substrate in the treatment container; and
an outer peripheral supply port formed at a position between the central supply port and the outside exhaust position; and
when a hydrophobization treatment is performed on only an outer peripheral portion of the front surface of the substrate in the treatment container, an inert gas as the first gas is supplied from the central supply port and the hydrophobizing gas is supplied as the first gas from the outer peripheral supply port.

8. A hydrophobization treatment method for performing a hydrophobization treatment on a substrate, comprising
selectively supplying a hydrophobizing gas from at least one of a first supply port provided above the substrate in a treatment container forming a treatment space and a second supply port provided at a position facing a central region of the substrate below the substrate in the treatment container.

9. The hydrophobization treatment method according to claim 8, wherein:
the first supply port has a central supply port formed at a position facing the second supply port across the substrate in the treatment container; and
at the selectively supplying the hydrophobizing gas, for the substrate whose both front surface and rear surface are hydrophobization treatment targets, the hydrophobizing gas to the front surface is supplied from the central supply port.

10. The hydrophobization treatment method according to claim 9, wherein
at the selectively supplying the hydrophobizing gas, for the substrate whose both the front surface and the rear surface are the hydrophobization treatment targets, the hydrophobizing gas is supplied to the front surface and the rear surface at a same time.

11. The hydrophobization treatment method according to claim 9, wherein
at the selectively supplying the hydrophobizing gas, for the substrate whose both the front surface and the rear surface are the hydrophobization treatment targets, the supply of the hydrophobizing gas to the front surface and the supply of the hydrophobizing gas to the rear surface are performed in order.

12. The hydrophobization treatment method according to claim 8, wherein:
the first supply port has a central supply port formed at a position facing the second supply port across the substrate in the treatment container; and
at the selectively supplying the hydrophobizing gas, for the substrate whose only front surface is a hydrophobization treatment target, the hydrophobizing gas is supplied from the central supply port and an inert gas is supplied from the second supply port.

13. The hydrophobization treatment method according to claim 8, wherein:
at the selectively supplying the hydrophobizing gas, an inside of the treatment container is exhausted from an upper outer peripheral exhaust port; and
the upper outer peripheral exhaust port is provided above and outside the substrate in the treatment container and opens to the treatment space.

14. The hydrophobization treatment method according to claim 8, wherein
the treatment container is configured such that an inside thereof is exhaustable from an exhaust position outside the substrate;
the first supply port has:
a central supply port formed at a position facing the second supply port across the substrate in the treatment container; and
an outer peripheral supply port formed at a position between the central supply port and the outside exhaust position; and
at the selectively supplying the hydrophobizing gas, for the substrate whose only outer peripheral portion of the front surface of the substrate is a hydrophobization treatment target, an inert gas is supplied from the central supply port and the hydrophobizing gas is supplied from the outer peripheral supply port.

15. A computer-readable storage medium storing a program running on a computer of a control unit for controlling a hydrophobization treatment apparatus to cause the hydrophobization treatment apparatus to execute a hydrophobization treatment method for performing a hydrophobization treatment on a substrate,
the hydrophobization treatment method comprising selectively supplying a hydrophobizing gas from at least one of a first supply port provided above the substrate in a treatment container forming a treatment space and a second supply port provided at a position facing a central region of the substrate below the substrate in the treatment container.
